(19) United States
(12) Patent Application Publication
(10) Pub. No.: US 2026/0018372 A1
(43) Pub. Date: Jan. 15, 2026

(54) Stage Device and Charged Particle Beam Device Using Same

(71) Applicant: Hitachi High-Tech Corporation, Tokyo (JP)

(72) Inventors: Takeru CHUMAN, Tokyo (JP); Motohiro TAKAHASHI, Tokyo (JP); Hironori OGAWA, Tokyo (JP); Shuichi NAKAGAWA, Tokyo (JP)

(21) Appl. No.: 19/214,185

(22) Filed: May 21, 2025

(30) Foreign Application Priority Data
Jul. 12, 2024 (JP) 2024-112294

(51) Int. Cl. H01J 37/20; H01J 37/28

(52) U.S. Cl. CPC H01J 37/20; H01J 37/28; H01J 2237/20228; H01J 2237/20235; H01J 2237/24585

(57) ABSTRACT

There is provided a stage device that, with a relatively simple configuration, can detect an abnormality such as wear of a driving mechanism by using a sensor incorporated in an actuator while achieving a lower floor of the driving mechanism that drives a stage in a Z-direction. The stage device includes a specimen table configured to support a specimen, an XY mechanism configured to move the specimen table in a horizontal direction, and a Z-mechanism configured to move the specimen table in a vertical direction. The Z-mechanism includes an actuator disposed in the horizontal direction and including a sensor capable of detecting an operation amount of the actuator itself, a converting mechanism configured to convert an output of the actuator from the horizontal direction to the vertical direction by elastic deformation, a spring element configured to connect the specimen table and the converting mechanism to each other, and a guiding element configured to suppress movement of the converting mechanism in the horizontal direction. The Z-mechanism drives the specimen table in the vertical direction by controlling the output of the actuator on the basis of an output of the sensor.

### CLAIM OF PRIORITY

The present application claims priority from Japanese Patent application serial no. 2024-112294, filed on Jul. 12, 2024, the content of which is hereby incorporated by reference into this application.

### BACKGROUND OF THE INVENTION

### 1. Field of the Invention

The present invention relates to a configuration of a stage device and control thereof, and particularly relates to a technique effectively applied to a charged particle beam device desired to perform high-speed and high-accuracy focusing by Z-direction driving of a specimen stage.

### 2. Description of the Related Art

A charged particle beam device such as an electron microscope used for the manufacture, measurement, inspection, and the like of semiconductor wafers is provided with a stage that moves the position of a specimen to irradiate a desired position of the specimen with an electron beam. Such a stage includes a driving mechanism for moving the specimen in at least two directions (XY direction) in order to move the specimen in a two-dimensional direction (XY direction).

In addition, there may also be a need to position the specimen in a direction (Z-direction) vertical to the two directions (XY direction) described above. For example, there is a case where focusing is performed by moving a specimen stage in the Z-direction instead of an adjustment using an electron optical system, or the like cases.

As a background technique of the present technical field, there is a technique as in JP-2005-79373-A, for example. JP-2005-79373-A discloses a “mechanism that corrects a deformation of a stage guide base, which deformation accompanies stage driving, by using a sensor-integrated piezoelectric actuator.

In JP-2005-79373-A, positioning is performed by deforming and translating the stage guide so as to retain a gap between a driven stage and the stage guide and flatness of the upper surface of the stage guide.

### SUMMARY OF THE INVENTION

According to the technique of JP-2005-79373-A described above, the deformation of a holding table can be corrected. However, in the case of a Z-mechanism in which the table and the actuator are directly connected to each other, the actuator needs to be enlarged in order to secure a stroke in the Z-direction. As a result, the center of gravity of the table is raised, and vibration increases. When vibration increases, a time necessary for the positioning is increased, and consequently throughput is decreased.

In addition, in a case where the table and the actuator are directly connected to each other, a change in posture due to backlash or wear of parts cannot be detected, which becomes a factor in causing a “visual field deviation” such that a position desired to be measured and an actual measurement position deviate from each other due to an inclination of the table.

It is accordingly an object of the present invention to provide a stage device and a charged particle beam device using the same that, with a relatively simple configuration, can detect an abnormality such as wear of a driving mechanism by using a sensor incorporated in an actuator while achieving a lower floor of the driving mechanism that drives a stage in the Z-direction.

In order to solve the above problems, the present invention includes a specimen table configured to support a specimen, an XY mechanism configured to move the specimen table in a horizontal direction, and a Z-mechanism configured to move the specimen table in a vertical direction, the Z-mechanism including an actuator disposed in the horizontal direction and including a sensor capable of detecting an operation amount of the actuator itself, a converting mechanism configured to convert an output of the actuator from the horizontal direction to the vertical direction by elastic deformation, a spring element configured to connect the specimen table and the converting mechanism to each other, and a guiding element configured to suppress movement of the converting mechanism in the horizontal direction, and the Z-mechanism being configured to drive the specimen table in the vertical direction by controlling the output of the actuator on the basis of an output of the sensor.

According to the present invention, it is possible to realize a stage device and a charged particle beam device using the same that, with a relatively simple configuration, can detect an abnormality such as wear of a driving mechanism by using a sensor incorporated in an actuator while achieving a lower floor of the driving mechanism that drives a stage in the Z-direction.

Hence, in an electron microscope, for example, high-speed and high-accuracy focusing through Z-direction driving of a specimen stage is made possible, which can contribute to improvements in image quality and throughput.

Problems, configurations, and effects other than those described above will be made apparent by the following description of embodiments.

### BRIEF DESCRIPTION OF THE DRAWINGS

FIG. 1 is a diagram illustrating a general configuration of a charged particle beam device according to a first embodiment of the present invention;

FIG. 2A is a diagram schematically illustrating a conventional actuator direct connection type Z-mechanism;

FIG. 2B is a diagram schematically illustrating a Z-mechanism (hinge system) according to the present invention;

FIG. 3 is a diagram schematically illustrating an operation (action) of a converting mechanism in the Z-mechanism of FIG. 2B;

FIG. 4A is a diagram schematically illustrating an output transmission path of the hinge system;

FIG. 4B is a diagram schematically illustrating the output transmission path of the hinge system;

FIG. 5 is a diagram illustrating an example of a structure of an XYZ-stage including the Z-mechanism (hinge system) according to the present invention;

FIG. 6 is a diagram illustrating a relation between an applied voltage and an amount of driving in a piezoelectric actuator;

FIG. 7A is a diagram illustrating a method of correcting a table posture by using an external sensor;

FIG. 7B is a diagram illustrating the method of correcting the table posture by using the external sensor; and

FIG. 8 is a diagram illustrating an example of a structure of a Z-stage according to a second embodiment of the present invention.

### DESCRIPTION OF THE PREFERRED EMBODIMENTS

Embodiments of the present invention will hereinafter be described with reference to the drawings. Incidentally, identical configurations in the drawings are identified by the same reference signs, and detailed description of duplicate parts will be omitted.

### First Embodiment

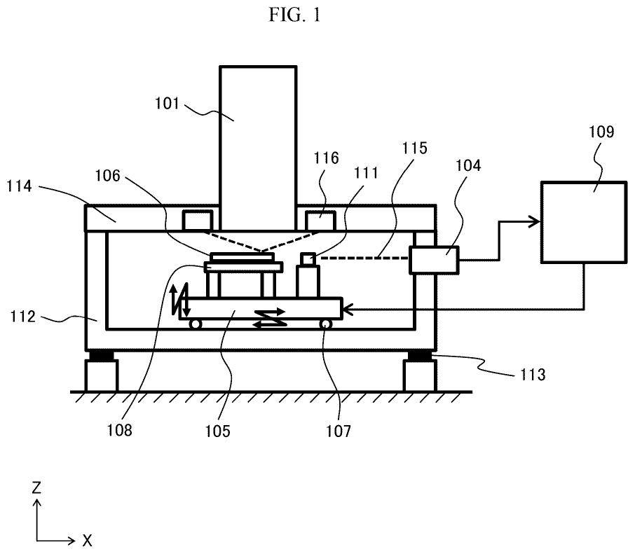

A stage device and a charged particle beam device using the same according to a first embodiment of the present invention will be described with reference to FIGS. 1 to 7B.

First, in order to facilitate understanding of the present invention, the background technique of the present invention described above and problems in the conventional technique will be described in more detail.

A recent semiconductor element inspecting device needs to perform a high-speed entire surface inspection of a wafer for defect inspection of a photomask as design rules have been miniaturized. As there is such a request, an electron microscope, for example, is desired to have a function of performing an operation of focusing an electron beam, that is, an autofocus (hereinafter, an AF) at high speed.

In order to perform the AF by driving a stage, a Z-stage for positioning a specimen in a vertical direction (Z-direction) needs to be included in addition to a conventional XY stage for positioning the specimen within a horizontal plane (XY plane). However, with a conventional ordinary Z-stage, the height of the mechanism increases with a stroke extension. There are thus problems of the rising of a gravity center and a necessity for a space. Accordingly, a Z-stage capable of low-floor and minute-movement positioning needs to be realized.

Each embodiment to be described in the following relates to a stage device constituted by a Z-mechanism including a converting mechanism that converts a horizontal direction output into that in the vertical direction in a XYZ-direction positioning stage. An XY stage including an ordinary Z-mechanism uses a wedge mechanism, which presents problems of an increase in heat generation and an increase in vibration due to an increase in movable mass and a decrease in rigidity.

A stage structure according to the present invention implements a Z-movement by a Z-mechanism including a converting mechanism that converts a horizontal direction output into that in the vertical direction, so that a stage structure is provided in which the stage can be thereby made to have a low center of gravity as compared with a direct connection type Z-mechanism, and at the same time, abnormality detection is made possible by a sensor included in an actuator.

Next, a charged particle beam device covered by the present invention will be described with reference to FIG. 1. FIG. 1 is a diagram illustrating a general configuration of the charged particle beam device in the present embodiment.

In the present embodiment, an example of a semiconductor measuring device (hereinafter, a length measurement scanning electron microscope (SEM)) will be described as an example of the charged particle beam device. In the length measurement SEM, an electron optical system lens barrel 101 is mounted on a specimen chamber 112, and the specimen chamber 112 is supported by a vibration isolating mount 113. An electron beam is applied onto a wafer 106 from the electron optical system lens barrel 101, and a pattern on the wafer 106 is imaged to perform the measurement of a line width of the pattern and the evaluation of shape accuracy.

A stage having a table 105 as a movable part is mounted within the specimen chamber 112. A chuck 108 mounted with the wafer 106 as an observation target is fixed to the table 105. In addition, the table 105 is supported by a guide 107. Stage coordinates are obtained by measuring the position of a mirror 111 by a laser interferometer 104, and positioning control is performed by a controller 109. In addition, a specimen height measuring sensor 116 can measure the upper surface height of the wafer 106.

In order to vary a distance to the electron optical system lens barrel 101 by moving the chuck 108 in an upward-downward direction (Z-direction), the table 105 necessitates a function of performing a movement in the vertical direction (Z-direction) in addition to a horizontal movement.

In addition, when a deformation and a vibration occur in the table 105, a relative distance between the chuck 108 and the mirror 111 varies, so that an image displacement or an image oscillation occurs in a case where the position of an observation point on the wafer 106 is managed on the basis of a laser length measurement value of the laser interferometer 104.

However, in a case where the table 105 is displaced or vibrated without an accompanying deformation, the relative distance between the chuck 108 and the mirror 111 does not change. Thus, when the electron beam is shifted by an amount of shift in a measured value of the present position of the stage obtained by measuring the position of the mirror 111, it is possible to prevent the displacement or the vibration of the table 105 from causing the image displacement or the image oscillation.

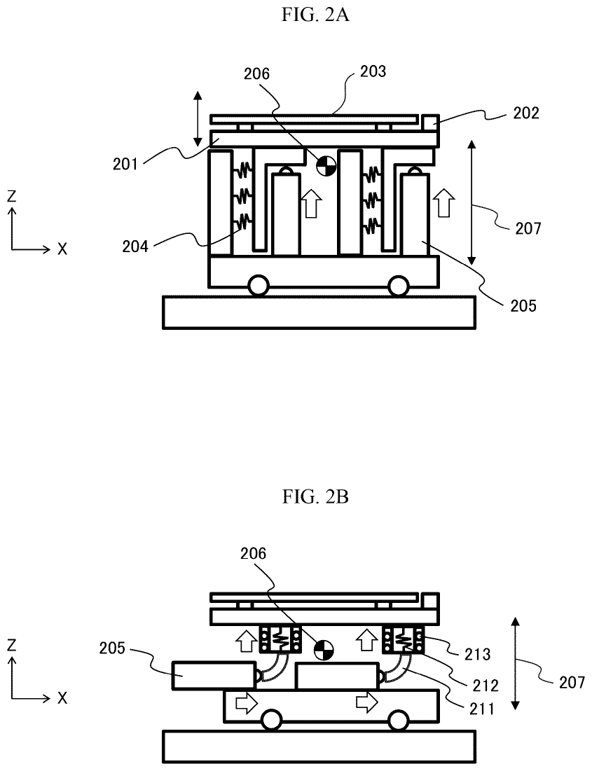

A conventional ordinary actuator direct connection type Z-stage mechanism will be described with reference to FIG. 2A. FIG. 2A is a diagram schematically illustrating the conventional actuator direct connection type Z-mechanism.

As illustrated in FIG. 2A, in the conventional Z-mechanism, in order to drive a top table 201 in the Z-direction, guides 204 restrict a degree of freedom in the X- and Y-directions, and actuators 205 perform driving in the Z-direction.

An electromagnetic motor, a piezoelectric actuator, a magnetostrictive actuator, an ultrasonic motor, or the like is used as the actuator 205. The piezoelectric actuator is generally used in a case where a minute distance movement is to be performed in these actuators. The stroke of an actuator suitable for the minute movement is approximately 1000 ppm for an actuator size. Thus, in order to obtain a long stroke, the size of the actuator itself is increased. A stage gravity center 206 is therefore raised, which is a cause of inviting a degradation in a vibration characteristic and an increase in a measurement error.

A Z-mechanism according to the present invention will be described with reference to FIG. 2B. FIG. 2B is a diagram schematically illustrating the Z-mechanism according to the present invention. In the following, this system will be referred to as a “hinge system.”

As illustrated in FIG. 2B, in contrast to the direct connection system of FIG. 2A, the hinge system according to the present invention has an actuator 205 arranged in a horizontal direction (XY direction) and converts a horizontal direction output (XY direction output) of the actuator 205 into that in the vertical direction (Z-direction) via an elastic hinge 211 to produce the output. In addition, the output converted into the vertical direction (Z-direction) by the elastic hinge 211 is transmitted to a table via a spring element 212 such as, for example, a leaf spring to drive the table in the Z-direction. In addition, a movement in the horizontal direction is suppressed by being restricted in the horizontal direction by a guiding element (guide) 213.

Here, the spring element 212 is not limited to a leaf spring, but a spring element such as a coil spring would be applicable as the constituent element. At the same time, the guiding element 213 is not limited to a rolling guide, a leaf spring, or the like either, and it suffices for the guiding element 213 to be an element that can perform restriction in the horizontal direction and ensure a degree of freedom in the vertical direction (Z-direction).

By way of the mechanism that converts the output from the horizontal direction (XY direction) to the vertical direction (Z-direction) as described above, it is possible to ensure a long stroke in a state in which the stage gravity center 206 is lowered and a stage height (Z-mechanism height) 207 is reduced.

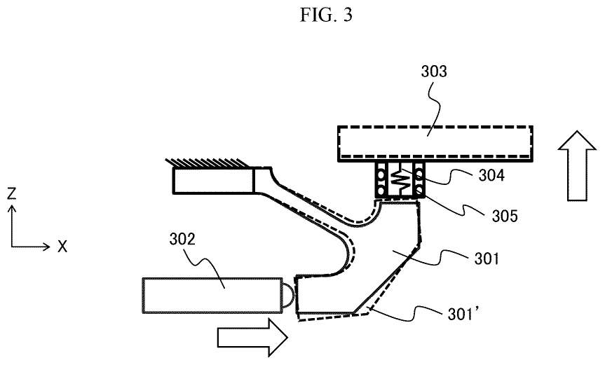

The elastic hinge 211 (301) that converts the horizontal direction output into that in the vertical direction will be described in detail with reference to FIG. 3. FIG. 3 is a diagram schematically illustrating an operation (action) of the converting mechanism in the Z-mechanism of FIG. 2B. Incidentally, in FIG. 3, the elastic hinge 301 is fixed to a fixing block not illustrated in the figure or the like.

As illustrated in FIG. 3, when the elastic hinge 301 fixed to the fixing block or the like receives a horizontal output in the X-direction of an actuator 302 at a lower end of the hinge, the whole of the hinge is elastically deformed as in a case of an elastically deformed hinge 301′. The elastic hinge 301 thereby converts the horizontal direction (X-direction) output into that in the vertical direction (Z-direction). The output converted into the vertical direction (Z-direction) is transmitted to a table 303 via a spring element 304 held by a guiding element (guide) 305, so that driving in the vertical direction is made possible.

At this time, when a horizontal direction input point and a vertical direction output point are set in point contact with the elastic hinge 301, a vertical direction displacement at the horizontal direction input point and a horizontal direction displacement at the vertical direction output point, which are caused by elastic deformation of the converting mechanism, can be removed by a slide.

The shape of the elastic hinge 301 is not limited to the shape illustrated in FIG. 3, but a shape that can convert the horizontal direction output into that in the vertical direction by elastic deformation would be applicable as the shape of the elastic hinge 301. In addition, a displacement scaling factor can freely be converted by appropriately selecting the input position of the horizontal direction output and the output position of the vertical direction output.

Incidentally, the elastic hinge 301 is preferably configured such that a point of intersection of an extension of an input surface of the elastic hinge 301, the output of the actuator 302 being input to the input surface, and an extension of an output surface of the elastic hinge 301, the output of the actuator 302 converted into the vertical direction being output from the output surface, is a pseudo rotational center of the elastic hinge 301, and the pseudo rotational center is located in a fixed portion of the elastic hinge 301.

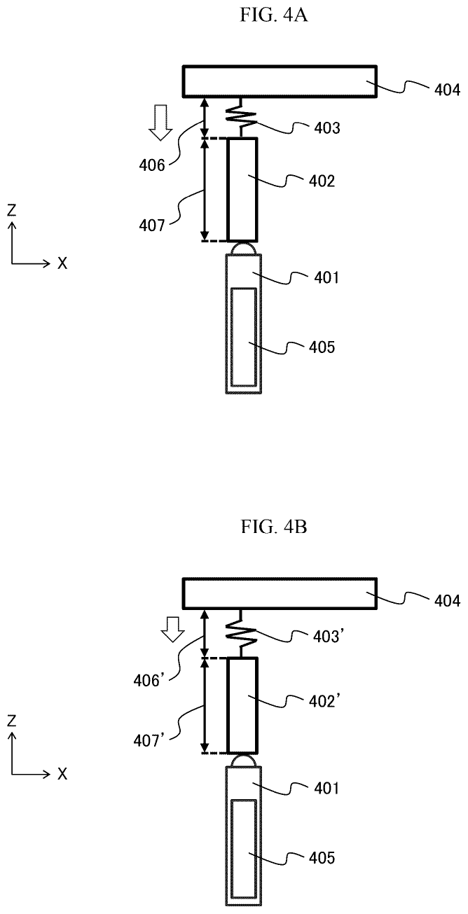

A principle of detecting an external force input from a table 404 side in the hinge system according to the present invention will be described with reference to FIG. 4A and FIG. 4B. FIG. 4A and FIG. 4B are each a diagram schematically illustrating an output transmission path of the hinge system. Incidentally, FIG. 4B represents a case where wear has occurred in an elastic hinge 402.

Consideration will be given to the output transmission path from an actuator 401 to a table 404 as illustrated in FIG. 4A. The elastic hinge (rigid body model corresponding to the elastic hinge) 402 that transmits an output merely changes the direction of the output and can therefore be considered to be a rigid body having a certain length. Hence, the force input to the actuator 401 depends on a reaction force generated by a spring element 403 that connects the table 404 and the elastic hinge 402 to each other. That is, when the table 404 is deformed and inclined by the external force, a spring element length (spring length at a normal time) 406 varies, and thus the spring reaction force changes.

This reaction force causes a minute displacement in the actuator 401, and the displacement is read by a built-in sensor 405. It is thereby possible to detect a variation in a table reaction force due to the inclination or the like. A strain sensor or the like, for example, is used as the sensor 405.

In addition, as illustrated in FIG. 4B, in a case where wear occurs between the elastic hinge 402 and the actuator 401 or the spring element 403, this case is equivalent to a change in a rigid body length 407′. When the rigid body length 407′ changes, a spring element length 406′ varies at the same time, and thus the spring reaction force changes. Hence, as in the case of a normal time in FIG. 4A, wear can be detected on the basis of a change in the output of the sensor 405.

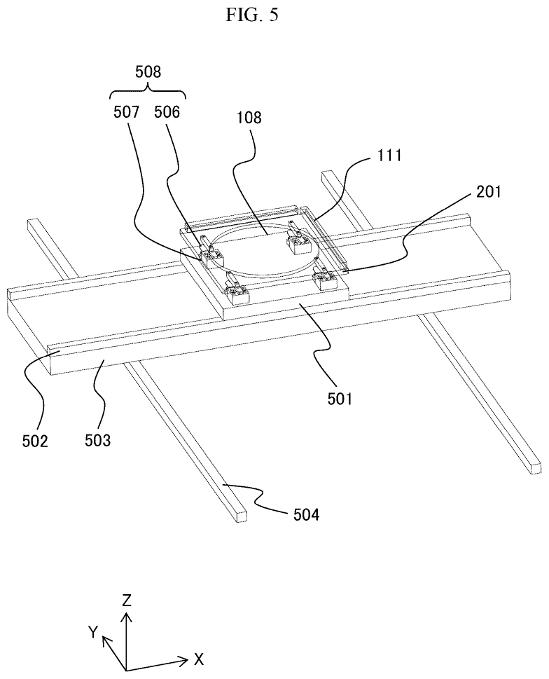

With reference to FIG. 5, description will be made of an example of an XY stage including a Z-stage of the hinge system in which a piezoelectric actuator is applied as an actuator. FIG. 5 is a diagram illustrating an example of a structure of an XYZ-stage including the Z-mechanism (hinge system) according to the present invention.

As illustrated in FIG. 5, a Y-table 503 is guided in the Y-direction by a Y-guide 504, and an X-table 501 is guided in the X-direction by an X-guide 502. A converting mechanism 507 and a piezoelectric actuator 506 are mounted on the X-table 501. A mirror (bar mirror) 111 and a chuck 108 are fixed to a top table 201. The top table 201 can be positioned in the Z-direction by Z-mechanisms 508 each constituted by the converting mechanism 507 and the piezoelectric actuator 506.

Incidentally, while the Z-stage including the Z-mechanism 508 can be disposed on the lower side of an XY mechanism, a prompt operation of the Z-mechanism 508 is difficult due to a high load in a case where the XY mechanism having a large mass is operated in a Z-axis direction as a gravitational direction. In the structure example illustrated in FIG. 5, the Z-stage is disposed on the XY mechanism, thereby reducing a Z-axis movable mass and enabling a prompt operation of the Z-mechanism 508.

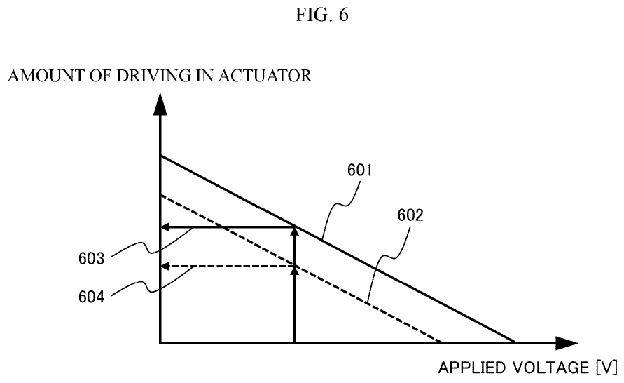

A principle of estimating an amount of wear from a sensor output will be described with reference to FIG. 6. FIG. 6 is a diagram illustrating a relation between an applied voltage and an amount of driving in a piezoelectric actuator.

When driving in the vertical direction is performed by using the Z-mechanism 508, variation occurs in a Z-direction output with respect to actuator output due to component variation within the mechanism and wear of constituent parts. In the case of the conventional actuator direct connection type Z-mechanism as illustrated in FIG. 2A, the force applied to the actuator is constant, and therefore the sensor within the actuator cannot detect wear or backlash.

Accordingly, by including the spring element in the Z-mechanism as in the Z-mechanism (hinge system) according to the present invention illustrated in FIG. 2B, it is possible to perform the detection of wear and the estimation of a wear amount by using the output of the sensor included in the actuator.

A relation between a force that can be output by the piezoelectric actuator and an elongation amount of the piezoelectric actuator is determined by a force applied to the main body of the actuator. The force applied to the actuator corresponds to a force input to the actuator by the spring element 304 via the elastic hinge 301 in the Z-mechanism (hinge system) according to the present invention.

In FIG. 6, a reference numeral 601 indicates a straight line representing a relation between the generated force and the elongation amount before the occurrence of wear, and a reference numeral 602 indicates a straight line obtained in a case where the force applied to the actuator varies due to wear.

As illustrated in FIG. 6, when the force applied to the actuator varies, actuator elongation amounts 603 and 604 in a case where an equal voltage is applied are different from each other. A reference numeral 603 indicates a driving amount in a case where a constant voltage is applied during a normal time. A reference numeral 604 indicates a driving amount in a case where a constant voltage is applied at a time of wear.

It is therefore possible to measure a variation in the force applied to the piezoelectric actuator and estimate an amount of wear of the Z-mechanism 508 by comparing the sensor output (piezoelectric actuator elongation amount) in a case where a specific voltage is applied before the occurrence of the wear (at a time of assembly) with the sensor output in a case where a similar voltage is applied at a time of the occurrence of the wear (during an operation).

This processing is performed in an arithmetic device (calculating unit) such as the controller 109 in FIG. 1, for example. That is, the arithmetic device (calculating unit) such as the controller 109 calculates an amount of wear and an amount of backlash of the Z-mechanism 508 by using the output of the sensor 405 at a time of assembly of the stage device and the output of the sensor 405 during the operation of the stage device.

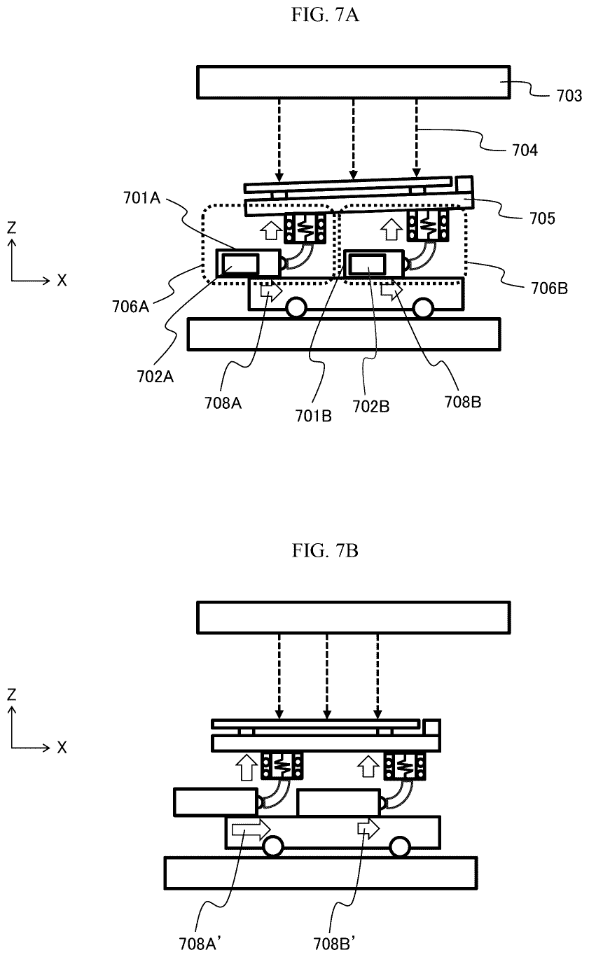

A method of correcting a table posture on the basis of an external sensor will be described with reference to FIG. 7A and FIG. 7B. FIG. 7A and FIG. 7B are diagrams illustrating the method of correcting the table posture by using the external sensor.

FIG. 7A illustrates a case where component variation within the Z-mechanism varies an amount of X-direction movement and thus deforms the table. A specimen height 704 is measured at a plurality of points of the specimen by using a sensor 703 capable of measuring the height of the upper surface of the specimen in a state in which actuators 701A and 701B are driven by a certain amount by using sensors 702A and 702B. At this time, the obtained specimen height 704 is a height including variation in each of Z-mechanisms 706A and 706B at a time of the measurement. Hence, driving amounts (elongation amounts) 708A and 708B of the actuators 701A and 701B are corrected such that the specimen height 704 is constant on the entire surface of the specimen.

As illustrated in FIG. 7B, by correcting driving amounts (elongation amounts) 708A′ and 708B′ of the actuators 701A and 701B, it is possible to make a posture correction in a state including component variation and wear of the Z-mechanisms 706A and 706B. In addition, wear of the Z-mechanisms 706A and 706B can be detected by the following procedure by use of the outputs of the sensors 702A and 702B and applied voltages at a time of the correction.

First, a voltage at a time of the correction is applied to each of the actuators 701A and 701B, and the respective sensor outputs of the sensors 702A and 702B are obtained. At this time, in a case where the outputs of the sensors 702A and 702B are different from the outputs at the time of the correction, a deviation in a load balance of a table 705 has occurred, and therefore the occurrence of wear or backlash within the Z-mechanisms can be detected. In this case, a worn Z-mechanism is supported by other Z-mechanisms via the table 705, and therefore the spring reaction force is decreased. The worn Z-mechanism can therefore be identified.

As described above, the stage device according to the present embodiment includes the specimen table (the chuck 108 or the top table 201) configured to support the specimen (wafer 106 or 203), the XY mechanism (the X-table 501, the X-guide 502, the Y-table 503, and the Y-guide 504) configured to move the specimen table in the horizontal direction, and the Z-mechanism 508, 706A, or 706B configured to move the specimen table in the vertical direction, the Z-mechanism including the actuator 205, 302, 401, 701A, or 701B disposed in the horizontal direction and including the sensor 405, 702A, or 702B capable of detecting an operation amount of the actuator itself, the converting mechanism (the elastic hinge 211 or 301 or the converting mechanism 507) configured to convert an output of the actuator from the horizontal direction to the vertical direction by elastic deformation, the spring element 212 or 304 configured to connect the specimen table and the converting mechanism to each other, and the guiding element 213 or 305 configured to suppress movement of the converting mechanism in the horizontal direction, and the Z-mechanism being configured to drive the specimen table in the vertical direction by controlling the output of the actuator on the basis of an output of the sensor.

In addition, a plurality of the Z-mechanisms 508, 706A, or 706B are provided, and the specimen table (the chuck 108 or the top table 201) is held by the plurality of the Z-mechanisms.

In addition, the output of the actuator 205, 302, 401, 701A, or 701B is corrected on the basis of an amount of wear of the Z-mechanism 508, 706A, or 706B calculated by the arithmetic device (calculating unit) such as the controller 109.

In addition, the specimen height measured by the external sensor (specimen height measuring sensor 116 or 703) and the output of the sensor 405, 702A, or 702B under a specific condition are compared with each other, and the output of the actuator 205, 302, 401, 701A, or 701B is corrected on the basis of a result of the comparison.

### Second Embodiment

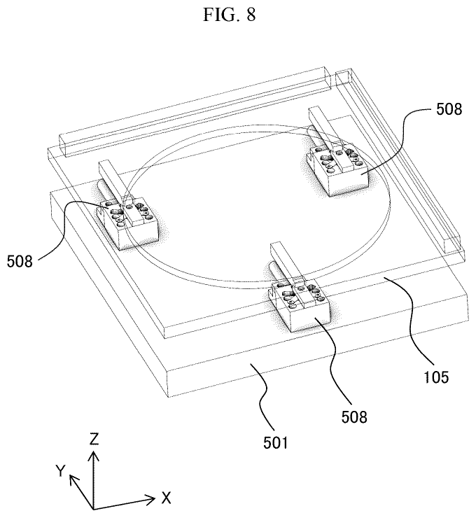

A stage device according to a second embodiment of the present invention will be described with reference to FIG. 8. FIG. 8 is a diagram illustrating an example of a structure of a Z-stage according to the present embodiment. FIG. 8 represents an example in which the number of Z-mechanisms 508 is set in three.

In the first embodiment (FIG. 5), a configuration example has been illustrated in which four Z-mechanisms 508 are arranged. However, the number of Z-mechanisms 508 can be set in three as in the present embodiment (FIG. 8).

As in a case where there are four Z-mechanisms 508, even when there is variation between the elongation amounts of the Z-mechanisms 508, it is possible to calculate a table plane by using the sensor outputs and suppress the deformation of the table 105.

It is to be noted that the present invention is not limited to the foregoing embodiments but includes various modifications. For example, the foregoing embodiments are described in detail to describe the present invention in an easily understandable manner and are not necessarily limited to embodiments including all of the described configurations. In addition, a part of a configuration of a certain embodiment can be replaced with a configuration of another embodiment, and a configuration of another embodiment can be added to a configuration of a certain embodiment as well. In addition, for a part of a configuration of each embodiment, another configuration can be added, deleted, or substituted.

What is claimed is:

1. A stage device comprising:
a specimen table configured to support a specimen;
an XY mechanism configured to move the specimen table in a horizontal direction; and
a Z-mechanism configured to move the specimen table in a vertical direction,
the Z-mechanism including
an actuator disposed in the horizontal direction and including a sensor capable of detecting an operation amount of the actuator itself,
a converting mechanism configured to convert an output of the actuator from the horizontal direction to the vertical direction by elastic deformation,
a spring element configured to connect the specimen table and the converting mechanism to each other, and
a guiding element configured to suppress movement of the converting mechanism in the horizontal direction, and
the Z-mechanism being configured to drive the specimen table in the vertical direction by controlling the output of the actuator on a basis of an output of the sensor.

2. The stage device according to claim 1, wherein
a plurality of the Z-mechanisms are provided, and
the specimen table is held by the plurality of the Z-mechanisms.

3. The stage device according to claim 1, wherein
the output of the actuator is transmitted to the converting mechanism by point contact between the actuator and the converting mechanism.

4. The stage device according to claim 1, wherein
the actuator is a piezoelectric actuator.

5. The stage device according to claim 1, wherein
the sensor is a strain sensor.

6. The stage device according to claim 1, comprising:
a calculating unit configured to calculate an amount of wear and an amount of backlash of the Z-mechanism by using the output of the sensor at a time of assembly of the stage device and the output of the sensor during an operation of the stage device.

7. The stage device according to claim 6, wherein
the output of the actuator is corrected on a basis of the amount of wear of the Z-mechanism calculated by the calculating unit.

8. The stage device according to claim 1, wherein
a specimen height measured by an external sensor and the output of the sensor under a specific condition are compared with each other, and the output of the actuator is corrected on a basis of a result of the comparison.

9. The stage device according to claim 1, wherein
the converting mechanism is configured such that a point of intersection of an extension of an input surface of the converting mechanism, the output of the actuator being input to the input surface, and an extension of an output surface of the converting mechanism, the output of the actuator converted into the vertical direction being output from the output surface, is a pseudo rotational center of the converting mechanism, and the pseudo rotational center is located in a fixed portion of the converting mechanism.

10. A charged particle beam device comprising:
the stage device according to claim 1.
